(19) United States
(12) Patent Application Publication
(10) Pub. No.: US 2004/0026682 A1
(43) Pub. Date: Feb. 12, 2004

(54) Nano-dot memory and fabricating same

(76) Inventor: Hai Jiang, Fremont, CA (US)

Correspondence Address: Hai Jiang, 46710 Crawfors St. #6, Fremont, CA, 94539, US

(21) Appl. No.: 10/453,325

(22) Filed: Jun. 3, 2003

Related U.S. Application Data
(60) Provisional application No. 60/389,270, filed on Jun. 17, 2002.

(51) Int. Cl. H01L 47/00

(52) U.S. Cl. 257/4

(57) ABSTRACT

A non-volatile resistive memory comprises of a nano-dot resistive element where the nano-dot acts as a resistive element or small heater. The nano-dot has a size in the range of 1-50 nm. The resistance value of nano-dot resistive element was changed by the atomic configuration of the nano-dot or resistive layer by a suitable pulse current flowing through the nano-dot to realize the storage of the information.

Cross-reference to related applications: This application claims the benefit of PPA No. 60/389,270, filed by Jun. 17, 2002 by the present inventor

Federally sponsored research: none

### FIELD OF THE INVENTION

The present invention relates to electrically operated resistive memory element, and particularly to the structure, materials, and fabrication of the memory element.

### THE BACKGROUND OF THE INVENTION

In the recent years, a great deal of effect has been devoted to develop various non-volatile resistive memories. Typically, this kind of memory consists of a resistive element which is located between two electrodes. The resistive element can switch in different resistance values (or states) by a pulse current or programming current to realize the storage of information. A typical example of memory using the resistive element to store the information is the electrically erasable phase change memories disclosed in U.S. Pat. No. 3,530,441 to Ovshinsky. In this memory, the resistive element is made of chalcogenide semiconductor. The resistance value of the memory switches through the different atomic configurations in the resistive element, from the high resistance in a generally amorphous to a low resistance in a generally crystalline state, while the atomic configuration of the resistive element was changed by the heating effect from a pulse current. Pulse current with different duration and current value results in different atomic configurations in the resistive element, and thus different resistance values. But this kind of memory has some limitations that prevent its widespread uses as a direct and universal replacement for the memories used in the fields such as computer and telecommunication. These limitations include: (a) relatively slow electric switch speed; (b) a relatively high programming energy requirement necessary to initiate a detectable change in resistance value; (c) higher cost per megabyte compared with other memories.

To overcome these limitations resulted from the relatively larger volume of phase-change memory material in the resistive element, a composite resistive material comprising a mixture of phase-change memory material and dielectric material was invented and disclosed by the same assignee in U.S. Pat. No. 5,825,046. Using this new resistive material, the volume of phase change memory material (also called active material) was decreased and resulted in improved performances such as lower input energy, shorter programming time, etc. Nevertheless, the minimum energy needed to program a memory element is still in the range of 0.1-2 nanojoules (10⁻⁹ Joules)

As mentioned above, the change of the resistance in a resistive memory is accomplished by heating the resistive element using a programming current which results in a change of the atomic configuration of the phase-change material and thus its resistance. In this situation, the energy required to program a memory cell is basically proportional to the volume of the resistive memory element material. For the most designs of this kind of memory, the resistive element material was filled in an opening which usually was formed by the method of photolithography and etching. The size of opening basically determines the volume of the resistive element material. How to reduce the opening size is challenge work due to the resolution of the photolithography process.

In another design of phase change memory, instead of forming an opening for phase change material, a resistive heater is formed in the above opening first. A layer of phase change material was then deposited on the heater. The part of phase change material adjacent to the heater was heated when the current flow through the heater and become amorphous or crystalline depending on the value and duration of the current. The size of heater determines heating area in phase change material. In this case, how to make a smaller heater is essentially the same challenge issue as making smaller opening for resistive element as said above.

The reduction of opening size or heater is limited by the resolution of the photolithography process. The typical minimum opening size that can be obtained by the current photolithography technique is in sub-micrometer, e.g., about 0.2 μm. This size basically determines the minimum resistive element size or the heater size. Herein we define resistive element size or heater as characteristic size of memory element. Considering a cubic resistive memory element, if the characteristic size is shrunk 10 times smaller, the volume of the resistive element will be 1000 times smaller. For example, if the characteristic size decreases from the 0.2 μm (2000 Å) to 0.02 μm (200 Å), the volume of the resistive element decreases from 8×10⁻³ μm³ to 8×10⁻⁶ μm³. And it is also meant that the energy needed to program a memory will be 1000 times smaller, approximately.

The advantage of decreasing the characteristic size of memory element is not only the decrease of programming energy, but also that the making much faster and higher density memory becomes possible. Therefore, reduction of the characteristic size of the memory element is a key for resistive memory to become a universal non-volatile memory and potential candidate to replace the memories currently extensively used in the computer and telecommunication.

On the other hand, the manufacture process of the conventional memory element is complicated due to the involvement of the multiple steps of photolithography process, especially, high resolution photolithography. These complex processes result in low yield and high cost. Therefore, seeking simpler and lower cost process to make resistive memories with smaller characteristic size is a significant work.

It is well known that when two different and unmixable materials are co-deposited onto a substrate they normally form a composite thin film with two separated phases containing each material. In some cases, one material may form the nano-dots embedded in another material, such as in the case of Fe/SiO₂ composite thin film (J. Applied Physics, Vol 84, 1998, p5693). In the present invention, we use this technique to fabricate resistive element or heater for the memory applications.

### SUMMARY OF THE INVENTION

An object of the present invention is to provide a new non-volatile resistive memory structure with extremely small resistive element or resistive heater. It is also an object of the present invention to provide some methods to make this memory structure and the resistive element. The extremely small size of the resistive element or resistive heater makes this memory have a good scalability and possibility to make high density memory.

These and other objects of present invention are accomplished by a memory element comprising two electrodes and a resistive element sandwiched in the electrodes. Two kinds of resistive element are defined in this invention: One is simple nano-dot resistive element in which the nano-dot acts as a resistive element. The resistance of nano-dot basically determines the resistance of the memory. Another one is composite nano-dot resistive element containing a resistive layer and a nano-dot layer. The nano-dot acts as a small heater and the programming current flowing through the nano-dot can heat the adjacent resistive layer. This heating results in change of resistance of the resistive layer by changing its phase. The resistive element may contain a single nano-dot resistive element or a lamination of nano-dot resistive element and a conductive layer.

### BRIEF DESCRIPTION OF THE DRAWINGS

FIG. 1 is a cross sectional view illustrating a memory element structure with a simple nano-dot resistive element.

FIG. 2 is a simplified and enlarged perspective view illustrating the structure of nano-dot layer.

FIG. 3 is a cross sectional view illustrating a memory element structure with a lamination of simple nano-dot resistive element and conductive layer.

FIG. 4 is a cross sectional view illustrating a memory element structure with a composite nano-dot resistive element.

FIG. 5 is a cross sectional view illustrating a memory element structure with a lamination of composite resistive element and a conductive layer

FIG. 6 is a simplified and perspective view illustrating memory array with simple nano-dot resistive elements.

FIG. 7 is a general process flow diagram to make nano-dot memory element.

### DETAILED DESCRIPTION OF THE INVENTION

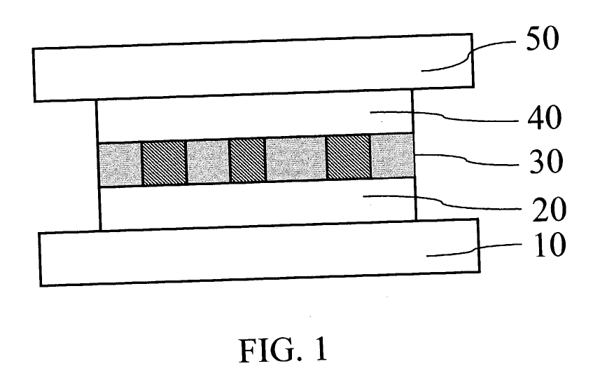

FIG. 1 is a cross sectional view illustrating a memory element structure with simple nano-dot resistive element. Basically, the memory comprises of 3 layers: electrode layers 20 and 40, nano-dot resistive layer 30. The electrode layers 20 and 40 are made of conductive material. They can also be made in multilayer thin films of different materials to ensure the electrode have a good conductivity electrically. The material of electrodes layer 20 and 40, or the layer contacting with nano-dot resistive layer in the case of multilayer electrode, should be chosen such that this material is not mixable with nano-dot material. So the layer contacting with the nano-dot 31 also functions as a barrier layer to prevent the atoms of the nano-dot 31 from diffusion into the adjacent layers 20 and 40 and the atoms of the adjacent layers 20 and 40 from diffusion to nano-dot 31. Also since the information is stored by changing the resistance of the nano-dot 31 resulted from the change of the atomic configuration due to the heating effect of programming current, the material of the electrode layers 20 and 40 is preferred, but not limited to be the some high melting temperature metal, alloy or conductive compound such as carbide and nitride, for example, WC, TiN.

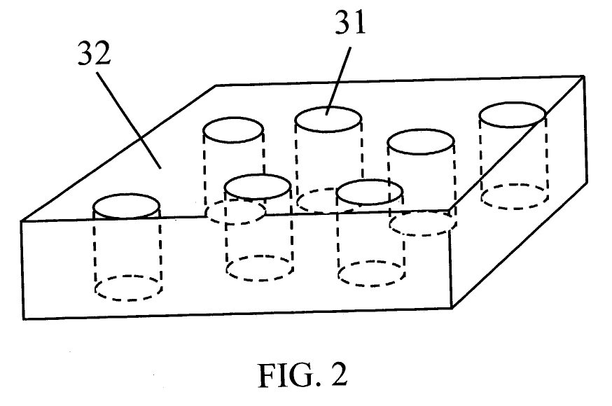

The nano-dot resistive element 30 is a layer where some resistive nano-dots 31 with size of about 1 nm to several tens nm (1 nm=10⁻⁹ m) embedded uniformly in a high resistance matrix 32, as shown in FIG. 2. The size of nano-dot is defined herein as the diameter of the dots, or their “characteristic dimension” which is equivalent to the diameter where the nano-dots are not cylindrically shaped. The nano-dot material has much smaller resisitivity than the matrix material so that current mainly flows through the nano-dots 31. The top surface and bottom surface of the nano-dot contact with top electrode and bottom electrode directly, respectively. Therefore, a single nano-dot itself constitutes a single resistor. The thickness of nano-dot resistive element 30 is about 1 nm to several tens nm, and more preferably of 3 nm to 50 nm.

The nano-dot resistive element 30 can be made by co-deposition of two unmixable materials: one is high resistive material which forms matrix 32 and another one is low resistive material which forms nano-dot 31. The nano-dot resistive element 30 can be made by various thin film deposition methods such as sputtering, evaporation, or the chemical vapor deposition (CVD). The preferred and simpler method is to co-sputter a composite target containing these two materials by the magnetron sputtering, RF sputtering or ion beam sputtering. The nano-dot material and high resistive matrix material were chosen such that they are not mixable. By optimizing the deposition conditions and selecting suitable materials, a well-defined nano-dot 31 with desired size can be formed and embed uniformly in the high resistive matrix. This layer can be also made by multilayer deposition of nano-dot material and high resistive material. In this case, a several angstroms of high resistive material and nano-dot material are deposited alternatively. After deposition, an anneal process maybe is required to form a nano-dot resistive element layer with well-defined nano-dot. To ensure the nano-dot was isolated by high resistive matrix material, the volume ratio of nano-dot material and high resistive matrix material should be less than 3/1, typically, in the range of 1/1˜1/100.

As mentioned above, the nano-dot material and high resistive matrix material were chosen such that they are not mixable. Selectable materials with this combination are extensively. The oxide, nitride, boride, carbide, boron, silicon, carbon, carboxynitride and mixture of these materials are the good candidates for high resistive matrix material, while most semiconductors, metals and alloys are the good candidates for the low resistive nano-dot materials.

Since the nano-dot 31 is isolated by the high resistive matrix material, the current flows mainly through the nano-dots. The resistance of the nano-dot 31 is determined by its atomic configuration. The atomic configuration of the nano-dot can be changed by the heating effect resulted from the programming current flowing through the nano-dot. It is possible to heat a nano-dot to its melting temperature by a pulse current with duration of nano-seconds. For example, for a 5×5×5 nm Cr nano-dot, a 10 nanosecond current pulse of about 5.0×10⁻² mA can heat this nano-dot to its melting temperature, i.e., 1890° C. The energy to melt this Cr nano-dot is about 10⁻¹⁶ Joule, an extremely low energy. The resistance of the Cr with size 5×5×5 nm is about 26 Ohms.

It is known that the atomic configuration or array of a material is changed with the temperature. The atoms of material become more disorder at higher temperature. Above the melting temperature at which the material is in liquid state, the atoms of material are disorder completely in long range. Because the nano-dot has very small size and is surrounded by the matrix layer 32, electrodes 20 and 40, the cooling rate of the particle after current pulse is extremely high so that the atomic configuration of the nano-dot at high temperature can be retained partly or completely at the room temperature. Therefore nano-dot with different atomic ordering and even amorphous state in which the atom array is disorder completely in long range can be obtained by a suitable pulse current. When nano-dot is in the amorphous state, the ordering degree of the atoms can be changed by anneal. Anneal is a process to heat the nano-dot to some temperature below melting point and then cool down to room temperature. For the nano-dot, a smaller but maybe longer duration pulse current than that used for melting may be used to anneal it and change its resistance value to realize the writing of the data in the memory. To read the data stored in the memory, as conventional resistive memory a sensing current can be used to read out the resistance representing the data. The sensing current is usually much smaller than the writing or programming current and hardly changes the atomic configuration and thus the resistance of the nano-dots.

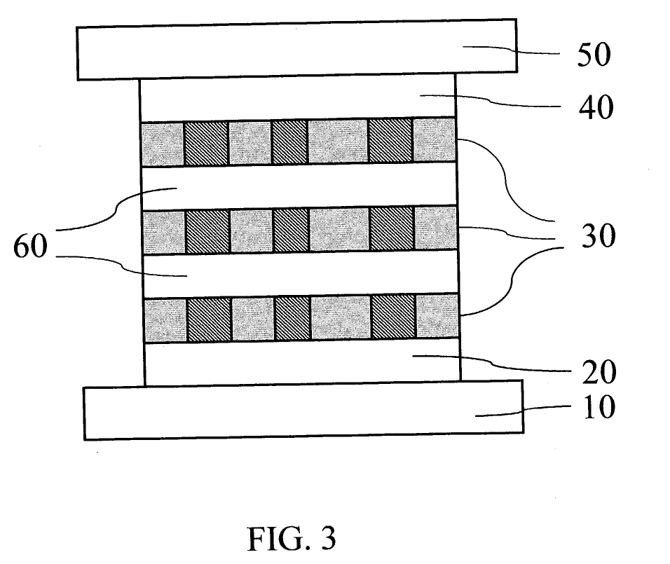

The resistance of the memory element can be changed by using a lamination of nano-dot resistive element and conductive layer. The memory element structure with lamination of simple nano-dot resistive element and conductive layer is shown in FIG. 3. The selection rule for the conductive 60 is the same as electrode layers 20 and 40. The advantages of laminated nano-dot resistive memory element are improved uniformity of the resistance of each memory element and to obtain a desired resistance value. These advantages are especially of importance when the memory element size becomes substantially smaller for the extra-high density memory. Since the number of the nano-dots in a single layer decreases with memory element size if the size of the nano-dot is constant. The less is the number of the nano-dot, the poorer is the uniformity of the resistance of the memory element. For example, if there is only one nano-dot in single nano-dot layer, the resistance of each memory element may change with the size of the nono-dot particle due to some variation in nano-dot size. So it is necessary to have certain number of nano-dots in a single memory to ensure a uniform resistance distribution.

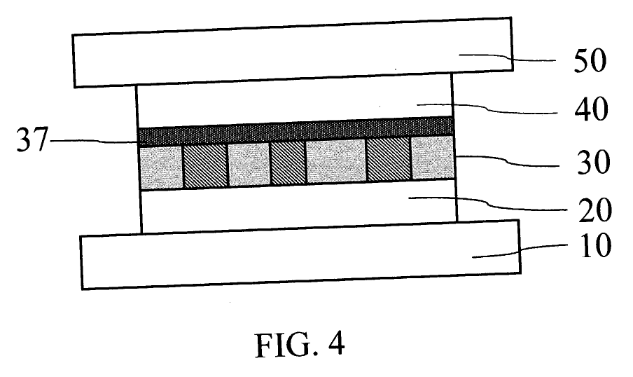

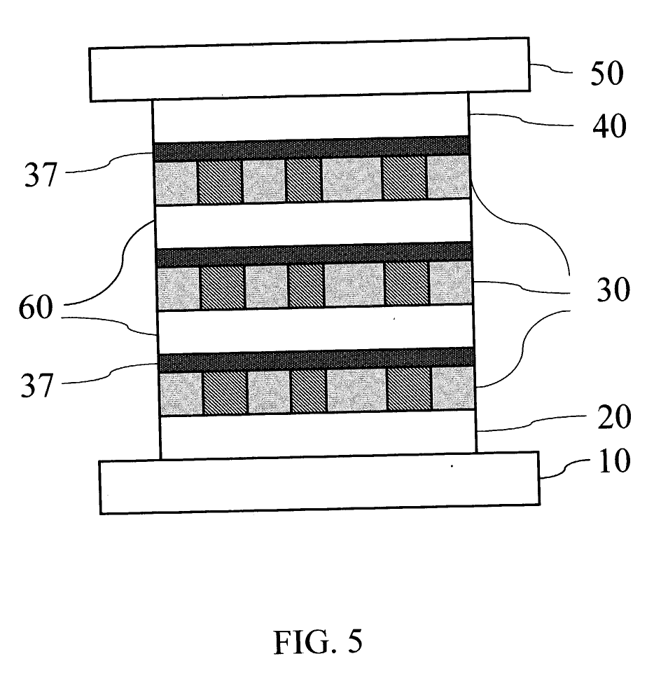

FIG. 4 is a cross sectional view illustrating a memory element structure with a composite nano-dot resistive element containing a nano-dot heater layer 30 and a resistive layer 37. In this structure, the nano-dot layer 30 functions as a nano-dot heater to heat the part of resistive layer 37 adjacent to the nano-dot. The requirement of the nano-dot layer is that the nano-dot is low resistive and matrix is high resistive. This requirement assures that the programing current flows through the nano-dots and thus can heat the part of resistive layer 37 adjacent to the nano-dot. Like simple nano-dot resistive element memory, the composite nano-dot resistive element can also be laminated with a conductive layer to improve the resistance uniformity of memory element, see FIG. 5.

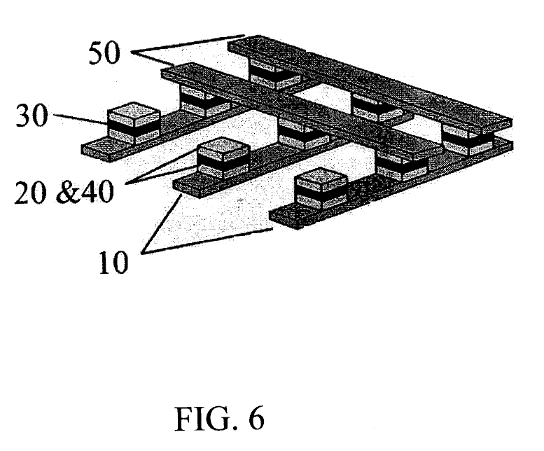

As any conventional memory element, the present memory element can be incorporated into the construction of very dense two-dimensional or three-dimensional memory arrays. FIG. 6 shows a portion of two-dimensional memory array with nano-dot resistive elements. The memory element including a simple nano-dot resistive layer 30 and electrode layers 20 and 40 that are located between the address lines. Here we define the bottom address line as X address line and top address line as Y address line.

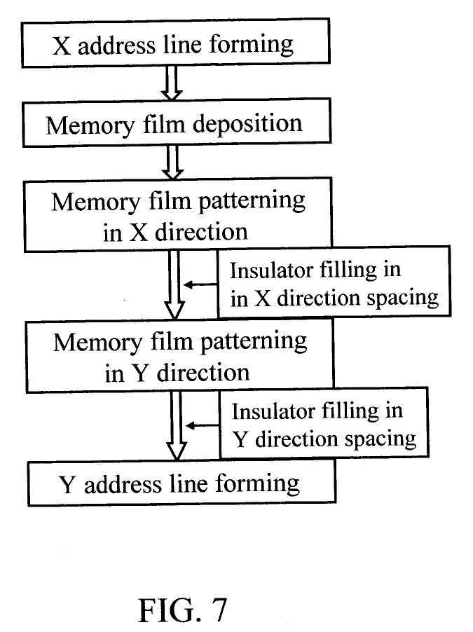

A general fabrication procedure of the present memory element is showed in FIG. 7. After forming the X address lines 10, the film stack of memory element including electrode 20 and 40, and nano-dot resistive element layer can be formed by thin film deposition. All, layers including electrodes 20&40 and nano-dot resistive element layer can be formed by a multiple step thin film deposition process. The process can be done without breaking vacuum in a deposition system with multiple targets. After deposition of the film stack of memory element including electrodes and nono-dot resistive element, the memory element can be patterned by the conventional methods of photolithography and etching processes. To obtain an approximate square memory element, memory element film needs to be patterned in X direction and Y direction, i.e., first forming a stripe in X direction and then forming an approximately square memory element. An insulator should be filled in the spacing between the memory elements in the X and Y directions. After finishing the memory element, the Y address lines are built on the memory element. Although not shown here, as conventional memory, some circuits need to be accomplished before and after fabricating memory elements to isolate the each memory element for reading and writing.

What is claim is:

1. Memory device comprising:
a. a pair of electrodes; and
b. a simple nano-dot resistive element containing only single nano-dot layer, or a composite nano-dot resistive element containing a nano-dot layer and a resistive layer, or
c. a lamination of a conductive layer and said simple nano-dot resistive element, or a lamination of a conductive layer and said composite nano-dot resistive element.

2. The device of claim 1 wherein the two detectable states are a high-resistance state and a low-resistance state.

3. The device of claim 1 wherein said nano-dot layer is a layer with lower resistive nano-dots embedded in higher resistive matrix.

4. The device of claim 1 wherein the size of the nano-dot is in the range of about 1.0-50 nm in diameter.

5. The volume ratio of said nano-dot and said high resistive matrix is in the range of about 3:1 to 1:500.

6. The device of claim 1 wherein the top and bottom surface of nano-dot contact directly with electrodes, and/or resistive layer.

7. The device of claim 1 with lamination of simple nano-dot resistive element and conductive layer wherein the top surface and bottom surface of nano-dot contact with adjacent said conductor layer, and/or electrodes.

8. The device of claim 1 with simple nano-dot resistive element wherein the resistive element has a thickness in the range of about 1.0 to 100 nm.

9. The device of claim 1 with composite nano-dot resistive element wherein the said nano-dot layer has a thickness in the range of about 1.0 to 100 nm.

10. The device of claim 1 with composite nano-dot resistive element wherein the said resistive layer has a thickness in the range of about 1.0 to 200 nm.

11. The device of claim 1 wherein the high resistive matrix material is one or more materials selected from the oxide, nitride, boride, carbide, boron, silicon, carbon, carboxynitride and mixture thereof.

12. The device of claim 1 wherein the nano-dot material is selected from a group of metals and half-metal elements, and the alloy comprising metal and half-metal elements.

13. The device of claim 1 with simple nano-dot resistive element wherein the nano-dot material is selected from semiconductors.

14. The device of claim 1 wherein the material of electrode layer and the conductive layer in the lamination resistive element is selected from the high melting temperature metals, alloys or conductive compounds.

15. The programming of the device of claim 1 includes a pulse current of short duration and higher current and a pulse current with longer duration and lower current.

16. The fabrication process of the resistive element film in claim 1 includes:
forming bottom electrode layer and
forming nano-dot resistive element layer over said electrode layer and
forming top electrode layer over the said nano-dot resistive layer
